(19) United States
(12) Patent Application Publication
(10) Pub. No.: US 2026/0344127 A1
(43) Pub. Date: Oct. 29, 2026

(54) SEMICONDUCTOR DEVICE

(71) Applicant: Ennostar Corporation, Hsinchu City (TW)

(72) Inventors: Chang-Tai HSIAO, Hsinchu (TW); Li-Shen TANG, Hsinchu (TW); Chih-Ming WANG, Hsinchu (TW); Yu-Chi WANG, Hsinchu City (TW); Min-Hsun HSIEH, Hsinchu City (TW); Hsiu-Yi LIN, Hsinchu City (TW)

(21) Appl. No.: 19/660,053

(22) Filed: Apr. 27, 2026

(30) Foreign Application Priority Data
Apr. 28, 2025 (TW) 114114646

(51) Int. Cl. H10H 20/85

(52) U.S. Cl. CPC H10H 20/8508

(57) ABSTRACT

A semiconductor device includes a substrate, a supporting layer, and a semiconductor element. The supporting layer is disposed on the substrate. In a cross-sectional view, the supporting layer comprises a first supporting pillar. The semiconductor element comprises a semiconductor stack and an insulating structure disposed on the semiconductor stack. The insulating structure comprises a main portion covering the semiconductor stack and a first extending portion extending outward from the main portion to the first supporting pillar. The first extending portion comprises a first thickness, and the main portion comprises a second thickness greater than the first thickness.

### CROSS REFERENCE TO RELATED APPLICATION

This application claims the right of priority based on TW Application Serial No. 114114646, filed on Apr. 28, 2025, and the content of which is hereby incorporated by reference in its entirety.

### Technical Field

The present disclosure relates to a semiconductor device, and particularly relates to a semiconductor device having one or a plurality of extending portions.

### Description of Background Art

Micro light-emitting diodes (micro-LEDs), owing to their high brightness, high energy efficiency, and miniaturized characteristics, have significant application potential in the field of display technology. However, since the micro-LED chips are extremely small, highly efficient mass transfer technique is required to enable large-scale manufacturing. Current mainstream mass transfer techniques include laser transfer, stamp transfer, and monolithic bonding.

Although mainstream techniques currently available on the market (e.g., laser transfer) offer high precision, they involve relatively high equipment costs and may readily cause damage to micro-LED chips. Monolithic bonding offers a relatively high degree of integration but is not suitable for all application scenarios. Stamp transfer technology, by contrast, has become a promising transfer approach due to its cost-effectiveness and broad applicability.

### SUMMARY OF THE DISCLOSURE

The present disclosure provides a semiconductor device. In some embodiments, the semiconductor device comprises a substrate, a supporting layer, and a semiconductor element. The supporting layer is disposed on the substrate. In a cross-sectional view, the supporting layer includes a first supporting pillar and a second supporting pillar that are separated from each other. The semiconductor element includes a semiconductor stack and an insulating structure. The insulating structure is disposed on the semiconductor stack. The insulating structure includes a main portion, a first extending portion, and a second extending portion. The first extending portion and the second extending portion are separated from each other. The main portion covers the semiconductor stack. The first extending portion extends outward from the main portion to the first supporting pillar. The second extending portion extends outward from the main portion to the second supporting pillar. A first thickness of the first extending portion is less than a second thickness of the main portion.

### BRIEF DESCRIPTION OF THE DRAWINGS

Embodiments of the present disclosure are described in detail below with reference to the accompanying drawings, and various features are not drawn to scale. In fact, dimensions of the various features may be enlarged or reduced to clearly illustrate technical features of the embodiments of the present disclosure.

FIG. 1A shows a schematic partial cross-sectional view of a semiconductor device according to some embodiments of the present disclosure.

FIG. 1B shows a schematic partial top view of a semiconductor device according to some embodiments of the present disclosure.

FIG. 1C shows a schematic partial perspective view of a semiconductor device according to some embodiments of the present disclosure.

FIGS. 2A- 2C show schematic diagrams of an insulating structure according to different embodiments of the present disclosure.

FIGS. 3A - 3H show schematic partial cross-sectional views of a semiconductor device in different manufacturing processes according to some embodiments of the present disclosure.

FIGS. 4A and 4B show schematic partial top views of a semiconductor device according to different embodiments of the present disclosure.

FIG. 5 shows a schematic partial top view of a semiconductor device according to other embodiments of the present disclosure.

FIG. 6 shows a partial enlarged view of a semiconductor device according to some embodiments of the present disclosure.

FIGS. 7A - 7F show schematic diagrams of a relative arrangement of a semiconductor element, an insulating structure, and a supporting layer according to different embodiments of the present disclosure.

FIG. 8 shows a schematic partial cross-sectional view of a semiconductor device according to other embodiments of the present disclosure.

FIGS. 9A - 9H show schematic partial cross-sectional views of a semiconductor device in different manufacturing processes according to other embodiments of the present disclosure.

FIG. 10 shows a schematic partial cross-sectional view of a semiconductor device according to still other embodiments of the present disclosure.

FIGS. 11A to 11C show schematic partial cross-sectional views of a semiconductor device according to different embodiments of the present disclosure.

FIG. 12A shows a schematic partial cross-sectional view of a semiconductor device according to still other embodiments of the present disclosure.

FIG. 12B shows a schematic partial top view of a semiconductor device according to still other embodiments of the present disclosure.

FIG. 13 shows a schematic cross-sectional view of a semiconductor assembly according to some embodiments of the present disclosure.

### DETAILED DESCRIPTION OF PREFERRED EMBODIMENTS

In the present disclosure, a semiconductor element may be, for example, a semiconductor optoelectronic element or a non-light-emitting element. The semiconductor optoelectronic element includes a light-emitting element (e.g., a light-emitting diode (LED) or a laser diode) or a light-absorbing element (e.g., a photodetector). Composition and dopants of respective layers in the semiconductor element of the present disclosure may be analyzed by any suitable method, such as secondary ion mass spectrometry (SIMS) or electrochemical capacitance-voltage (ECV) measurement. The thicknesses of the respective layers may also be analyzed by any suitable method, such as transmission electron microscopy (TEM) or scanning electron microscopy (SEM).

In the present disclosure, directional terms such as “on”, “below”, and “between” are intended to describe relative positions among objects and are not intended to limit absolute positions of the objects. In addition, terms “dispose” and “connect” may include situations that two structures are movable or fixed. Furthermore, terms such as “first” and “second” are used to designate different components or to distinguish different embodiments or scopes and are not intended to limit upper or lower bounds on number of the components, nor to limit manufacturing order or placement order of the components.

In some embodiments, the general formula InGaP may represent Inx0Ga1-x0P, in which 0 < x0 < 1; the general formula AlInP may represent Alₓ₁In₁₋ₓ₁P, in which 0 < x1 < 1; the general formula InGaN may represent Inₓ₂Ga₁₋ₓ₂N, in which 0 < x2 < 1; the general formula AlGaN may represent Alₓ₃Ga₁₋ₓ₃N, in which 0 < x3 < 1; the general formula AlGaInP may represent Alₓ₄Gaₓ₅In₁₋ₓ₄₋ₓ₅P, in which 0 < x4 < 1 and 0 < x5 < 1; the general formula InGaAsP may represent Inₓ₆Ga₁₋ₓ₆Asₓ₇P₁₋ₓ₇, in which 0 < x6 < 1 and 0 < x7 < 1; the general formula AlGaInAs may represent Alₓ₈Gaₓ₉In₁₋ₓ₈₋ₓ₉As, in which 0 < x8 < 1 and 0 < x9 < 1; the general formula InGaAs may represent Inₓ₁₀Ga₁₋ₓ₁₀As, in which 0 < x10 < 1; the general formula AlGaAs may represent Alₓ₁₁Ga₁₋ₓ₁₁As, in which 0 < x11 < 1; the general formula AlGaAsP may represent Alₓ₁₂Ga₁₋ₓ₁₂Asₓ₁₃P₁₋ₓ₁₃, in which 0 < x12 < 1 and 0 < x13 < 1; the general formula InGaNAs may represent Inₓ₁₄Ga₁₋ₓ₁₄Nₓ₁₅As₁₋ₓ₁₅, in which 0 < x14 < 1 and 0 < x15 < 1; and the general formula AlInGaN may represent Alₓ₁₆Inₓ₁₇Ga₁₋ₓ₁₆₋ₓ₁₇N, in which 0 < x16 < 1 and 0 < x17 < 1. The composition of each element can be adjusted for different purposes, such as but not limited to tuning the bandgap. In addition, when the semiconductor device is a light-emitting device, the dominant wavelength or the peak wavelength of the light-emitting device can also be adjusted accordingly.

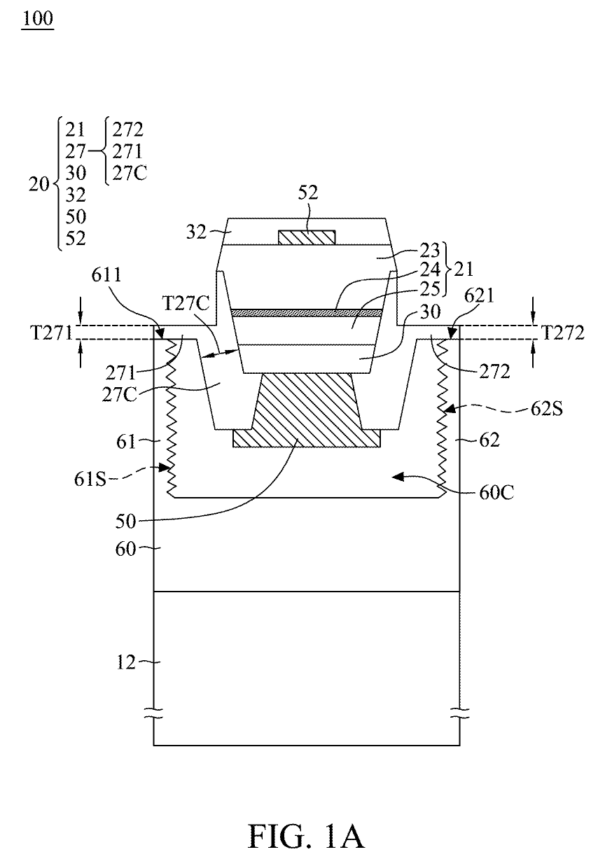

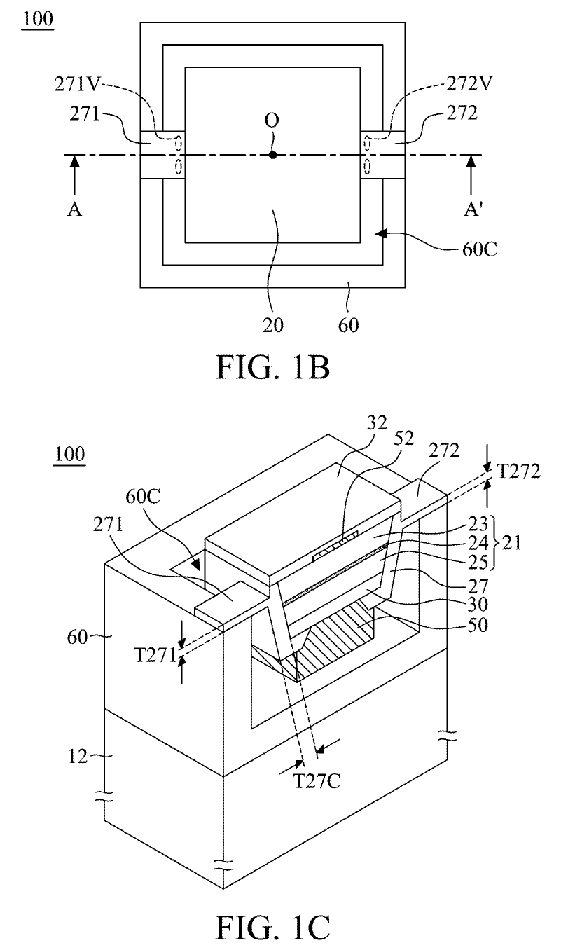

Referring to FIG. 1A, FIG. 1A shows a schematic partial cross-sectional view of a semiconductor device 100 according to some embodiments of the present disclosure. In some embodiments, the semiconductor device 100 includes a substrate 12. In some embodiments, the substrate may be a sapphire substrate, a plastic substrate, a ceramic substrate, or a glass substrate. In some embodiments, the semiconductor device 100 further includes a supporting layer 60 disposed on the substrate 12. As shown in FIG. 1A, in a cross-sectional view, the supporting layer 60 may include a first supporting pillar 61 and a second supporting pillar 62 spaced apart from each other. In some embodiments, the first supporting pillar 61 and the second supporting pillar 62 are respectively located at the left and right sides of the supporting layer 60. The first supporting pillar 61 includes an upper surface 611, and the second supporting pillar 62 includes an upper surface 621. The supporting layer 60 may include a dielectric material, such as a polymer material (e.g., benzocyclobutene (BCB), epoxy, polyimide, or silicone), alumina (Al₂O₃), or silicon oxide (SiO₂).

The semiconductor device 100 further includes a semiconductor element 20. As shown in FIG. 1A, a cavity 60C may be formed between the first supporting pillar 61 and the second supporting pillar 62. The semiconductor element 20 may include a semiconductor stack 21 and an insulating structure 27. The semiconductor stack 21 may include a first semiconductor structure 23, an active region 24, and a second semiconductor structure 25. The insulating structure 27 is connected to the semiconductor stack 21. As shown in FIG. 1A, the semiconductor stack 21 of the semiconductor element 20 may be, for example, suspended over the supporting layer 60. The semiconductor stack 21 is not in direct contact with the supporting layer 60. The insulating structure 27 may include an oxide, a nitride, or a fluoride, such as titanium oxide (TiO₂), silicon oxide (SiO₂), aluminum nitride (AlN), aluminum oxide (Al₂O₃), magnesium fluoride (MgF₂), or tantalum oxide (Ta₂O₅).

In some embodiments, the first semiconductor structure 23, the active region 24, and the second semiconductor structure 25 may each include a single layer or multiple layers. The first semiconductor structure 23 and the second semiconductor structure 25 located on opposite sides of the active region 24 may be asymmetric in appearance. As shown in FIG. 1A, the first semiconductor structure 23 includes a first minimum width, and the second semiconductor structure 25 includes a second minimum width less than the first minimum width. The first semiconductor structure 23 has a first conductivity type, and the second semiconductor structure 25 has a second conductivity type different from the first conductivity type. The first semiconductor structure 23 and the second semiconductor structure 25 may respectively provide electrons and holes (or holes and electrons). For example, the first conductivity type may be n-type, and the second conductivity type may be p-type; or the first conductivity type may be p-type, and the second conductivity type may be n-type. Each layer in the first semiconductor structure 23, the active region 24, and the second semiconductor structure 25 may include a binary III-V semiconductor material, such as GaN, GaAs, or GaP; a ternary III-V semiconductor material, such as InGaN, AlGaN, InGaAs, AlGaAs, InGaP, or AlInP; or a quaternary III-V semiconductor material, such as AlInGaN, AlGaInAs, AlGaInP, InGaAsP, or AlGaAsP. The conductivity types of the first semiconductor structure 23 and the second semiconductor structure 25 may be adjusted by adding different dopants. For example, the first semiconductor structure 23 may include a first dopant, and the second semiconductor structure 25 may include a second dopant different from the first dopant. The first dopant and the second dopant may each be a Group II, Group IV, or Group VI element in the periodic table, such as magnesium (Mg), zinc (Zn), carbon (C), silicon (Si), germanium (Ge), or tellurium (Te). In some embodiments, the first dopant is silicon (Si) or germanium (Ge), and the second dopant is magnesium (Mg) or carbon (C).

The active region 24 is located between the first semiconductor structure 23 and the second semiconductor structure 25. In some embodiments, the active region 24 may include a quantum well (QW) layer, such as indium gallium nitride (InGaN) or gallium nitride (GaN). In other embodiments, the active region 24 includes a multiple quantum well (MQW) structure. Electrons and holes may recombine in the active region 24 to emit light having a peak wavelength. The emitted light may be visible or invisible and may be incoherent light or coherent light. Specifically, the peak wavelength may depend on the material composition of the active region 24. For example, when the material of the active region 24 includes AlGaN, ultraviolet light having a peak wavelength ranging from 250 nm to 400 nm may be emitted; when the material of the active region 24 includes InGaN, deep blue light or blue light having a peak wavelength ranging from 400 nm to 490 nm, green light or yellow light having a peak wavelength ranging from 490 nm to 550 nm, or red light having a peak wavelength ranging from 560 nm to 650 nm may be emitted; when the material of the active region 24 includes InGaP or AlGaInP, yellow light, orange light, or red light having a peak wavelength ranging from 530 nm to 700 nm may be emitted; and when the material of the active region 24 includes InGaAs, InGaAsP, AlGaAs, or AlGaInAs, infrared light having a peak wavelength ranging from 700 nm to 1700 nm may be emitted.

As shown in FIG. 1A, in some embodiments, the insulating structure 27 includes a main portion 27C, a first extending portion 271, and a second extending portion 272. The first extending portion 271 and the second extending portion 272 are separated from each other. The main portion 27C covers the semiconductor stack 21. The first extending portion 271 and the second extending portion 272 respectively extend outward from the main portion 27C to the first supporting pillar 61 and the second supporting pillar 62, and the first extending portion 271 and the second extending portion 272 are respectively connected to the first supporting pillar 61 and the second supporting pillar 62. As shown in FIG. 1A, the first extending portion 271 and the second extending portion 272 may not overlap the semiconductor stack 21 in a vertical direction. In some embodiments, the main portion 27C, the first extending portion 271, and the second extending portion 272 may have different materials.

The first extending portion 271 has a first thickness T271, the second extending portion 272 has a second thickness T272, and the main portion 27C has a third thickness T27C. The first thickness T271 or the second thickness T272 may be different from the third thickness T27C. In some embodiments, the first thickness T271 of the first extending portion 271 may be less than the third thickness T27C of the main portion 27C. The second thickness T272 of the second extending portion 272 may be less than the third thickness T27C of the main portion 27C. In some embodiments, the first thickness T271 may be less than or equal to 400 nm, for example, in a range from 50 nm to 200 nm. In some embodiments, the second thickness T272 may be less than or equal to 400 nm, for example, in a range from 50 nm to 200 nm. In some embodiments, the third thickness T27C may be greater than or equal to 200 nm, for example, in a range from 300 nm to 3000 nm. In some embodiments, a ratio of the first thickness T271 or the second thickness T272 to the third thickness T27C may be, for example, in a range from 1/4 to 1/60. In some embodiments, when the ratio of the first thickness T271 or the second thickness T272 to the third thickness T27C falls within the range (i.e., 1/4 to 1/60), structural stability of the semiconductor device 100 may be maintained, thereby improving a success rate of subsequent transfer of the semiconductor element 20.

As shown in FIG. 1A, in some embodiments, a width of the first semiconductor structure 23 first gradually increases and then gradually decreases in a direction away from the active region 24 and the second semiconductor structure 25. In addition, in some embodiments, the insulating structure 27 is devoid of covering a portion of the first semiconductor structure 23 where the width gradually decreases.

FIG. 1B shows a schematic partial top view of the semiconductor device 100 according to some embodiments of the present disclosure. FIG. 1C shows a schematic partial perspective view of the semiconductor device 100 according to some embodiments of the present disclosure. For example, FIG. 1C may be a schematic perspective cross-sectional view taken along line A-A’ in FIG. 1B. For ease of understanding, part of the structure of the semiconductor element 20 is omitted in FIG. 1B. As shown in FIG. 1B, in a top view, the first extending portion 271 and the second extending portion 272 may be symmetrically arranged with respect to a geometric center O of the semiconductor element 20, thereby maintaining the position of the semiconductor element 20 and keeping the semiconductor element 20 balanced. The supporting layer 60 may surround the semiconductor element 20, and the semiconductor element 20 is connected to the supporting layer 60 through the first extending portion 271 and the second extending portion 272.

As shown in FIG. 1B, in some embodiments, the first extending portion 271 may optionally have one or more voids 271V, and the second extending portion 272 may also optionally have one or more voids 272V. By providing the voids 271V and the voids 272V, the semiconductor element 20 can be more easily broken in a subsequent transfer process, and the fracture location can be better controlled. In some embodiments, the semiconductor stack 21 may have an inverted trapezoidal shape. As shown in FIG. 1C, a width of the semiconductor stack 21 gradually decreases from the first semiconductor structure 23 toward the second semiconductor structure 25.

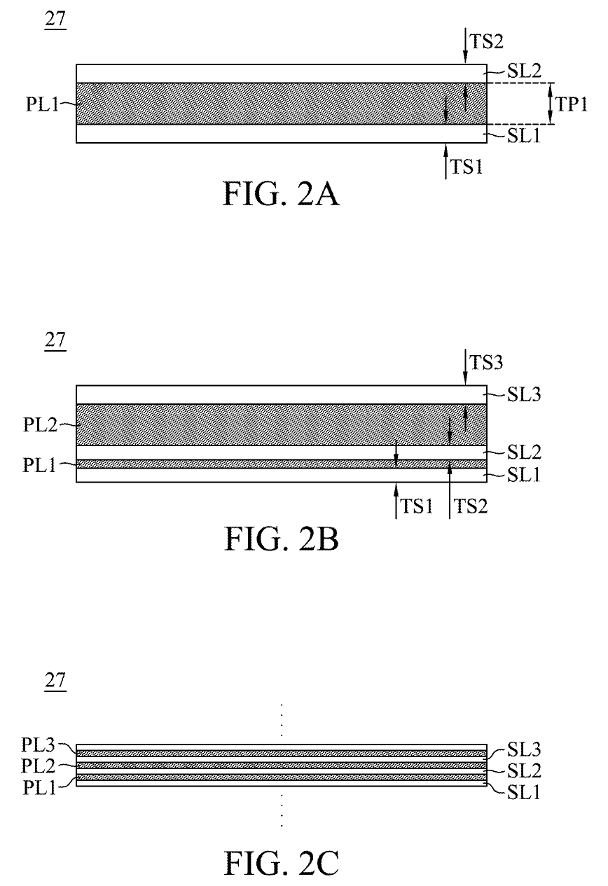

FIGS. 2A - 2C show schematic diagrams of an insulating structure 27 according to different embodiments of the present disclosure. FIGS. 2A -2C are described with reference to the main portion 27C. However, the first extending portion 271 and/or the second extending portion 272 may also have any structure or a partial structure shown in FIGS. 2A - 2C. As shown in FIGS. 2A -2B, the main portion 27C may include one or more first sub-layers (e.g., SL1/SL2/SL3) and one or more second sub-layers (e.g., PL1/PL2/PL3). The first sub-layers and the second sub-layers have different Mohs hardnesses. The first sub-layers have a first Mohs hardness, and the second sub-layers have a second Mohs hardness less than the first Mohs hardness. In some embodiments, the first sub-layers may serve as etch stop layers, and the second sub-layers may serve as passivation layers. In some embodiments, each of the first sub-layers includes aluminum oxide (Al₂O₃), which has a Mohs hardness of about 9, and each of the second sub-layers includes silicon dioxide (SiO2) or titanium dioxide (TiO₂), which has a Mohs hardness of about 6 to 7.

As shown in FIG. 2A, the main portion 27C includes two first sub-layers SL1, SL2 and a second sub-layer PL1 disposed between the first sub-layers SL1, SL2. A thickness TS1 of the first sub-layer SL1 and a thickness TS2 of the first sub-layer SL2 may each be in a range from 400 Å to 1500 Å. The first sub-layers SL1, SL2 may have substantially the same thickness. A thickness TP1 of the second sub-layer PL1 may be in a range from 8000 Å to 12000 Å. In some embodiments, the thickness TP1 > the thickness TS1 > the thickness TS2. For example, the thickness TS1 may be in a range from 1000 Å to 3000 Å, the thickness TP1 may be in a range from 6000 Å to 10000 Å, and the thickness TS2 may be in a range from 400 Å to 1500 Å.

As shown in FIG. 2B, in some embodiments, the main portion 27C includes three first sub-layers SL1, SL2, and SL3 and two second sub-layers PL1 and PL2 disposed between the first sub-layers SL1, SL2, and SL3. In some embodiments, the first sub-layers SL1, SL2, and SL3 have different thicknesses from one another. For example, a thickness TS3 of the first sub-layer SL3 may be greater than or equal to a thickness TS1 of the first sub-layer SL1 and a thickness TS2 of the first sub-layer SL2.

As shown in FIG. 2C, in some embodiments, the main portion 27C may include a structure similar to a distributed Bragg reflector (DBR). The main portion 27C includes a plurality of first sub-layers (SL1, SL2, SL3) and a plurality of second sub-layers (PL1, PL2, PL3) stacked alternately. The number of the first sub-layers and the number of the second sub-layers may be adjusted according to actual requirements. For example, the main portion 27C may include 3 to 20 pairs of the first sub-layers and the second sub-layers. The first sub-layers and the second sub-layers have different refractive indices. Specifically, the first sub-layers and the second sub-layers may include oxides or nitrides, such as aluminum oxide (Al₂O₃), silicon oxide (SiO₂), titanium oxide (TiO₂), silicon nitride (Si₃N₄), tantalum oxide (Ta₂O₅), or niobium oxide (Nb₂O₅). In some embodiments, a combination of the first sub-layers and the second sub-layers may be, for example, SiO₂/TiO₂ or SiO₂/Nb₂O₅. In some embodiments, the structures shown in FIGS. 2A - 2C may also be combined with or substituted for one another. For example, the structure shown in FIG. 2A or FIG. 2B may further include the DBR structure shown in FIG. 2C; alternatively, one or more layers in the structure shown in FIG. 2A or FIG. 2B, such as the second sub-layer PL1 or PL2, may be replaced with the DBR structure shown in FIG. 2C.

In some embodiments, the first extending portion 271 and/or the second extending portion 272 may be structures formed from the remaining first sub-layer SL1. Since the first sub-layer (e.g., Al₂O₃, having a Mohs hardness of about 9) has a higher Mohs hardness than the second sub-layer (e.g., SiO₂ or TiO₂, having a Mohs hardness of about 6 to 7), the first sub-layer is more brittle, thereby increasing likelihood that fracture will occur at the first extending portion 271 or the second extending portion 272 during subsequent transfer of the semiconductor element 20. In some embodiments, after local thinning of the insulating structure 27, the first extending portion 271 or the second extending portion 272 may include the first sub-layer SL1 and the second sub-layer PL1 (or may include the first sub-layer SL1, the second sub-layer PL1, and the first sub-layer SL2). Specifically, by using the first sub-layer (SL1/SL2) in the insulating structure 27 as an etch stop layer, the first thickness T271 of the first extending portion 271 and the second thickness T272 of the second extending portion 272 can be easily controlled, thereby improving thickness uniformity and structural stability. In some embodiments, since the first extending portion 271 and/or the second extending portion 272 includes a DBR structure, multiple interfaces in the DBR structure can also increase likelihood that fracture will occur at the first extending portion 271 or the second extending portion 272 during subsequent transfer of the semiconductor element 20.

Referring to FIGS. 1A, 1B and 1C, the semiconductor element 20 may optionally include conductive connecting layers 30 and 32 respectively disposed on the second semiconductor structure 25 and the first semiconductor structure 23. For example, the conductive connecting layers 30 and 32 may include a transparent conductive oxide, such as indium tin oxide (ITO), tin oxide (TO), indium zinc oxide (IZO), indium gallium zinc oxide (IGZO), indium zinc tin oxide (ITZO), antimony tin oxide (ATO), or antimony zinc oxide (AZO). The conductive connecting layers 30 and 32 may, for example, facilitate current spreading in the semiconductor element 20 and/or form favorable contact with the semiconductor stack 21 (e.g., ohmic contact).

As shown in FIGS. 1A, 1B AND 1C, the semiconductor element 20 may further include electrodes 50, 52. The electrode 50 may be electrically connected to the second semiconductor structure 25, and the electrode 52 may be electrically connected to the first semiconductor structure 23. The electrodes 50, 52 may include, for example, a metal or an alloy. In some embodiments, the metal may include germanium (Ge), beryllium (Be), zinc (Zn), gold (Au), nickel (Ni), platinum (Pt), palladium (Pd), iridium (Ir), titanium (Ti), chromium (Cr), tungsten (W), aluminum (Al), or copper (Cu). In some embodiments, the alloy may include at least two of the above metals, such as germanium-gold-nickel (GeAuNi), beryllium-gold (BeAu), germanium-gold (GeAu), or zinc-gold (ZnAu).

As shown in FIG. 1A, in some embodiments, through material combinations of the main portion 27C, the first extending portion 271, and the second extending portion 272, and/or the design of the relative relationship among the thickness T271, the thickness T27C, and the thickness T272, the first extending portion 271 and the second extending portion 272 can be easily broken during a subsequent process for transferring the semiconductor element 20, thereby improving a success rate of transferring the semiconductor element 20.

As shown in FIG. 1A, a portion of the semiconductor element 20 is disposed in the cavity 60C, and another portion of the semiconductor element 20 may extend beyond the upper surface 611 of the first supporting pillar 61 or the upper surface 621 of the second supporting pillar 62 in the vertical direction. Specifically, a portion of the second semiconductor structure 25 of the semiconductor element 20, the conductive connecting layer 30, the electrode 50, and a portion of the insulating structure 27 may be disposed in the cavity 60C, while other portions of the semiconductor element 20 extend upward beyond the upper surface 611 (or the upper surface 621). In some embodiments, the active region 24 is at a higher elevation than the upper surface 611 of the first supporting pillar 61 or the upper surface 621 of the second supporting pillar 62. The insulating structure 27 covers a sidewall of the second semiconductor structure 25, a portion of a sidewall of the first semiconductor structure 23, and a sidewall and part of a bottom surface of the conductive connecting layer 30. As shown in FIG. 1A, in some embodiments, the first supporting pillar 61 includes a sidewall 61S, and the sidewall 61S may optionally have a roughened structure facing the semiconductor stack 21. Similarly, in some embodiments, the second supporting pillar 62 includes a sidewall 62S, and the sidewall 62S may optionally have a roughened structure facing the semiconductor stack 21.

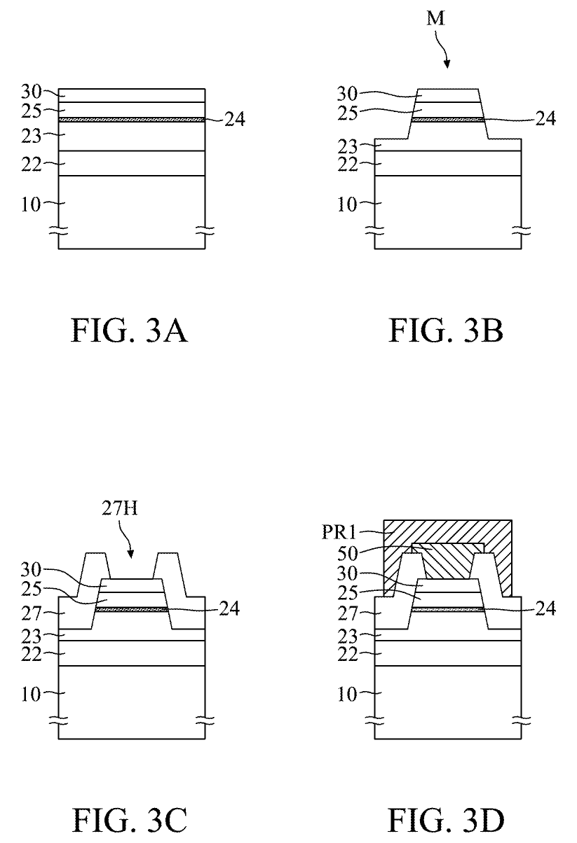

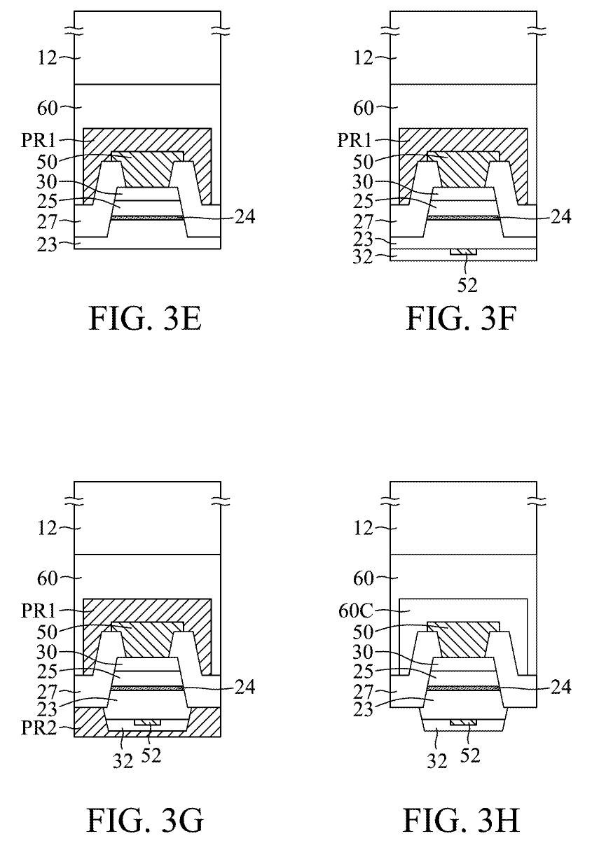

FIGS. 3A -3H show schematic partial cross-sectional views of a semiconductor device 100 in different manufacturing processes according to some embodiments of the present disclosure. For the sake of simplicity, some components of the semiconductor device 100 are omitted in FIGS. 3A-3H. As shown in FIG. 3A, in some embodiments, a semiconductor layer 22, a first semiconductor structure 23, an active region 24, and a second semiconductor structure 25 are sequentially formed on the growth substrate 10. In some embodiments, the growth substrate 10 may be patterned sapphire substrate (PSS), gallium arsenide (GaAs), indium phosphide (InP), gallium phosphide (GaP), or gallium nitride (GaN). The growth substrate 10 may optionally include a patterned surface, and the semiconductor layer 22 is directly formed on the patterned surface.

In some embodiments, the semiconductor layer 22 may be an undoped semiconductor layer or a lightly doped semiconductor layer (e.g., having a dopant concentration of less than 1×10¹⁷ cm⁻³). The semiconductor layer 22, the first semiconductor structure 23, the active region 24, and the second semiconductor structure 25 may be sequentially formed on the growth substrate 10 through an epitaxial growth process. In some embodiments, the epitaxial growth process may include metal-organic chemical vapor deposition (MOCVD), hydride vapor phase epitaxy (HVPE), or molecular beam epitaxy (MBE). Next, the conductive connecting layer 30 is formed on the second semiconductor structure 25. In some embodiments, the conductive connecting layer 30 may be formed through a deposition process, such as physical vapor deposition, chemical vapor deposition, atomic layer deposition, evaporation, or sputtering.

Then, as shown in FIG. 3B, in some embodiments, portions of the first semiconductor structure 23, the active region 24, the second semiconductor structure 25, and the conductive connecting layer 30 are removed to form a mesa region M on the first semiconductor structure 23. Specifically, this may be accomplished by forming a mask layer (not shown) on the conductive connecting layer 30 through a deposition process, and performing a patterning process (e.g., an etching process) using the mask layer. In some embodiments, the deposition process may include spin-on coating, chemical vapor deposition, or atomic layer deposition. In some embodiments, the etching process may include dry etching or wet etching. In some embodiments, the dry etching process may include reactive ion etching (RIE), inductively coupled plasma (ICP) etching, neutral beam etching (NBE), or electron cyclotron resonance (ECR) etching. In some embodiments, the wet etching process may use hydrofluoric acid (HF), or ammonium hydroxide (NH₄OH).

As shown in FIG. 3C, in some embodiments, an insulating structure 27 is formed on the mesa region M. The insulating structure 27 may be formed through a deposition process and a patterning process. Next, an opening 27H is formed in the insulating structure 27 to expose a portion of a surface of the conductive connecting layer 30.

As shown in FIG. 3D, in some embodiments, an electrode 50 is formed on the conductive connecting layer 30 and the insulating structure 27. The electrode 50 fills the opening 27H. Next, a sacrificial layer PR1 is formed on the electrode 50 and the insulating structure 27. The electrode 50 and the sacrificial layer PR1 may be formed through the deposition process.

As shown in FIG. 3E, a bonding process is performed to bond the sacrificial layer PR1 to the substrate 12 by means of the supporting layer 60. The supporting layer 60 may be in direct contact with the sacrificial layer PR1 and the insulating structure 27. As shown in FIG. 3F, an electrode 52 and a conductive connecting layer 32 are formed on the first semiconductor structure 23. Similarly, the electrode 52 and the conductive connecting layer 32 may be formed through the deposition process.

As shown in FIG. 3G, a portion of the conductive connecting layer 32 and a portion of the first semiconductor structure 23 are removed to expose the insulating structure 27. Next, in some embodiments, a mask layer PR2 is formed on portions of the conductive connecting layer 32, the first semiconductor structure 23, and the insulating structure 27. Then, using the mask layer PR2 as an etching mask, the insulating structure 27 is patterned so that the insulating structure 27 includes one or more extending portions (referring to FIG. 1B).

As shown in FIG. 3H, the mask layer PR2 is removed, and the sacrificial layer PR1 may be further removed to form a cavity 60C between the electrode 50 and the supporting layer 60. In some embodiments, the insulating structure 27 may optionally be further thinned so that the first thickness T271 of the first extending portion 271 and the second thickness T272 of the second extending portion 272 are less than the third thickness T27C of the main portion 27C (referring to FIG. 1A). The above thinning step may be performed, for example, by the etching process (e.g., ICP). The roughened structures of the sidewall 61S and the sidewall 62S are, for example, formed during the above thinning step. In some embodiments, the thinning step may further increase volume of the cavity 60C, thereby improving the success rate for transferring the semiconductor element 20.

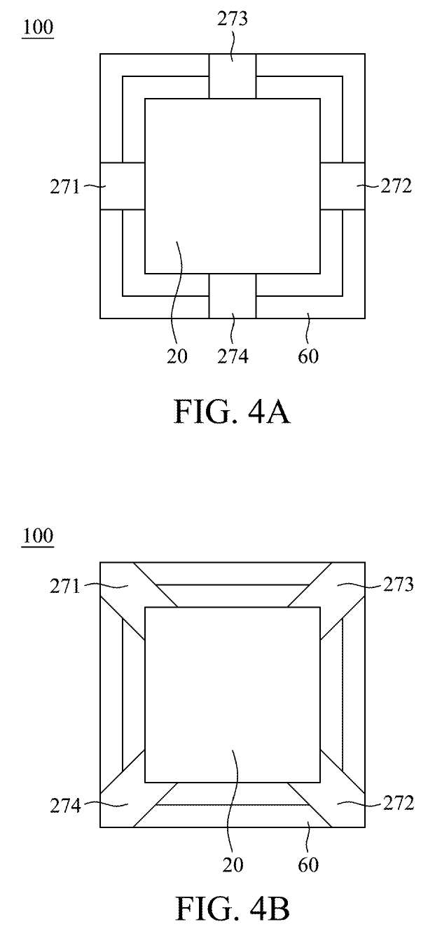

In the foregoing embodiments, the insulating structure 27 of the semiconductor device 100 has been described by taking a configuration in which the insulating structure 27 includes two extending portions (e.g., the first extending portion 271 and the second extending portion 272) as an example. FIGS. 4A and 4B show schematic partial top views of a semiconductor device 100 according to different embodiments of the present disclosure. As shown in FIGS. 4A and 4B, in some embodiments, the insulating structure 27 further includes a third extending portion 273 and a fourth extending portion 274. As shown in FIG. 4A, the semiconductor element 20 is quadrilateral (e.g., rectangular or square), and the first extending portion 271, the second extending portion 272, the third extending portion 273, and the fourth extending portion 274 respectively correspond to centers of the four sides of the quadrilateral, extend outward, and are connected to the supporting layer 60. As shown in FIG. 4B, the semiconductor element 20 is quadrilateral (e.g., rectangular or square), and the first extending portion 271, the second extending portion 272, the third extending portion 273, and the fourth extending portion 274 respectively correspond to four corners of the quadrilateral, extend outward, and are connected to the supporting layer 60. Number and shapes of the extending portions of the insulating structure 27 may be adjusted according to actual requirements.

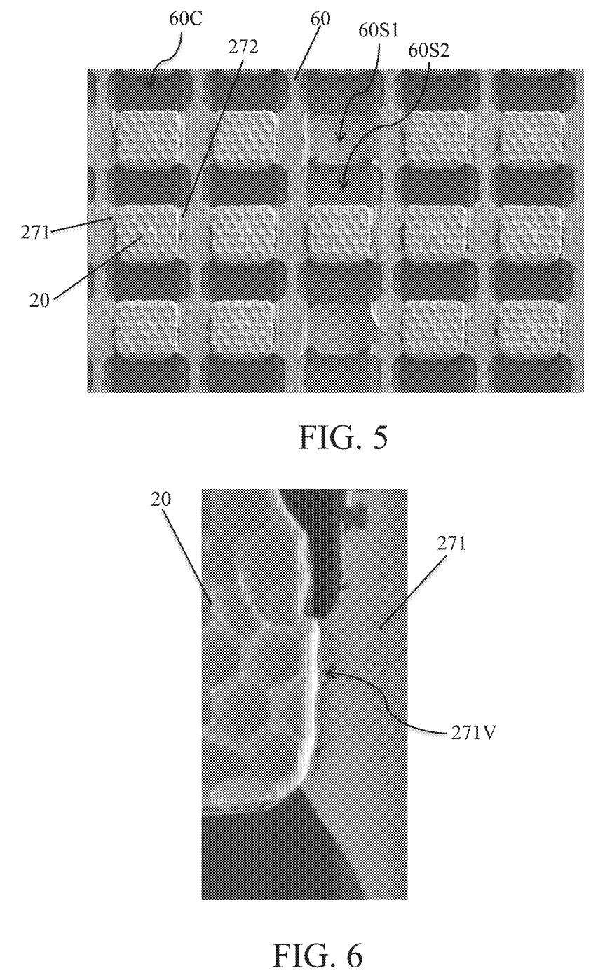

FIG. 5 shows a schematic partial top view of a semiconductor device 100 according to other embodiments of the present disclosure, which is obtained by scanning electron microscopy (SEM). As shown in FIG. 5, a plurality of semiconductor elements 20 may be arranged in an array. There are gaps between the plurality of semiconductor elements 20 in the same row, while semiconductor elements 20 in different rows are separated by the supporting layer 60. For ease of illustrating, the first and third semiconductor elements 20 in the third row are removed. As shown in FIG. 5, in some embodiments, the supporting layer 60 includes a first surface 60S1 and a second surface 60S2. Specifically, the first surface 60S1 corresponds to positions under the respective semiconductor elements 20, and the second surface 60S2 corresponds to gap positions between the semiconductor elements 20 in the same row. The first surface 60S1 and the second surface 60S2 are not coplanar. That is, the first surface 60S1 may be located below the semiconductor elements 20, a region above the second surface 60S2 is not covered by the semiconductor elements 20, and the first surface 60S1 is higher than the second surface 60S2 in the vertical direction. Specifically, in the steps shown in FIGS. 3G and 3H, a portion of the supporting layer 60 is protected by the overlying semiconductor elements 20 and the mask layer PR2. Therefore, after the sacrificial layer PR1 is removed, the first surface 60S1 is higher than the second surface 60S2, which is not protected by any structure.

FIG. 6 shows a partial enlarged view of a semiconductor device 100 according to some embodiments of the present disclosure, which is obtained by the SEM analysis and shows a connection between the insulating structure 27 and the semiconductor element 20. As shown in FIG. 6, in some embodiments, the first extending portion 271 of the insulating structure 27 may have one or more voids 271V. In a subsequent process for transferring the semiconductor element 20, the voids 271V can make the semiconductor element 20 more easily break away from the first extending portion 271. Similarly, the second extending portion 272 of the insulating structure 27 may also have one or more voids (not shown), which will not be described further.

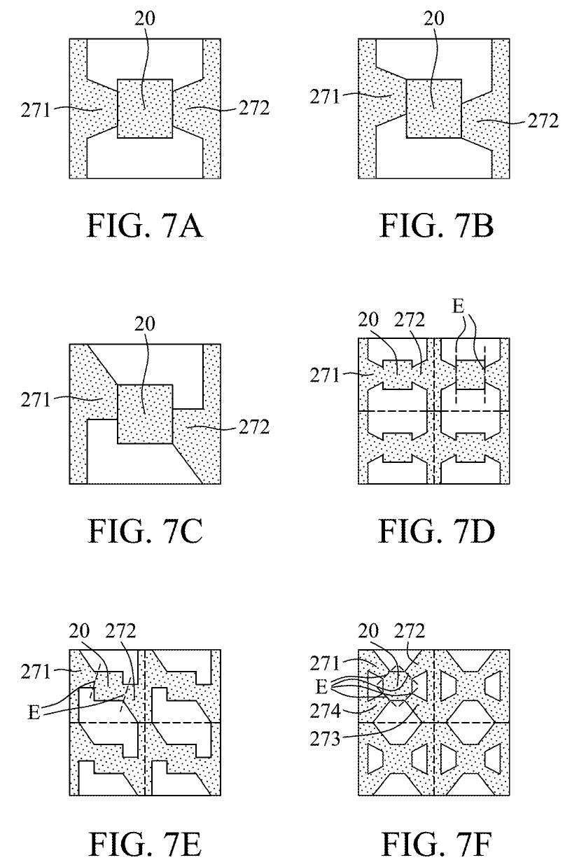

FIGS. 7A - 7F show schematic diagrams of a relative arrangement of a semiconductor element 20, an insulating structure 27 (which may include one or more first extending portions 271 and one or more second extending portions 272), and a supporting layer 60 (which may include the first supporting pillar 61 and the second supporting pillar 62) according to different embodiments of the present disclosure.

As shown in FIGS. 7A, 7B and 7 C, in some embodiments, the first extending portion 271 and the second extending portion 272 of the insulating structure 27 are respectively located on two sides of the semiconductor element 20. Specifically, in FIG. 7A, the first extending portion 271 and the second extending portion 272 are respectively located at central positions on the two sides of the semiconductor element 20. In FIGS. 7B and 7C, the first extending portion 271 is located at a position toward an upper part of the left side of the semiconductor element 20, and the second extending portion 272 is located at a position toward a lower part of the right side of the semiconductor element 20.

In some embodiments, a width of the first extending portion 271 gradually increases from the semiconductor element 20 toward the first supporting pillar 61, and a width of the second extending portion 272 gradually increases from the semiconductor element 20 toward the second supporting pillar 62, thereby making the semiconductor element 20 more likely to break away from narrower sides of the first extending portion 271 and the second extending portion 272 during a subsequent transfer process, such as stamp transfer.

As shown in FIGS. 7D, 7E, and 7F, in some embodiments, a plurality of semiconductor elements 20 (e.g., four semiconductor elements 20) is arranged in an array. As shown in FIGS. 7D and 7E, the first extending portion 271 and the second extending portion 272 of the insulating structure 27 are respectively located on two sides of each corresponding semiconductor element 20. Specifically, as shown in FIG. 7D, the first extending portion 271 and the second extending portion 272 are respectively located at the central positions of the two sides of the corresponding semiconductor element 20. As shown in FIG. 7E, the first extending portion 271 is located at a position toward the upper part of the left side of the corresponding semiconductor element 20, and the second extending portion 272 is located at a position toward the lower part of the right side of the corresponding semiconductor element 20. As shown in FIG. 7F, the semiconductor element 20 includes a first extending portion 271, a second extending portion 272, a third extending portion 273, and a fourth extending portion 274. The first extending portion 271 is located at an upper-left corner of the corresponding semiconductor element 20, the second extending portion 272 is located at an upper-right corner of the corresponding semiconductor element 20, the third extending portion 273 is located at a lower-right corner of the corresponding semiconductor element 20, and the fourth extending portion 274 is located at a lower-left corner of the corresponding semiconductor element 20. Number and positions of the extending portions of the insulating structure 27 may be adjusted according to actual requirements.

Similarly, width of each extending portion (e.g., the first extending portion 271, the second extending portion 272, the third extending portion 273, and the fourth extending portion 274) may gradually increase in a direction from near the semiconductor element 20 to farther away from the semiconductor element 20, thereby allowing the semiconductor element 20 to more easily break away from a side closer to the semiconductor element 20 (i.e., locations of multiple dashed-lines E shown in FIGS. 7D, 7E and 7 F,) during a subsequent transfer process, such as stamp transfer. In some embodiments, this design helps reduce portions of the extending structures remaining on the semiconductor element 20 after transfer.

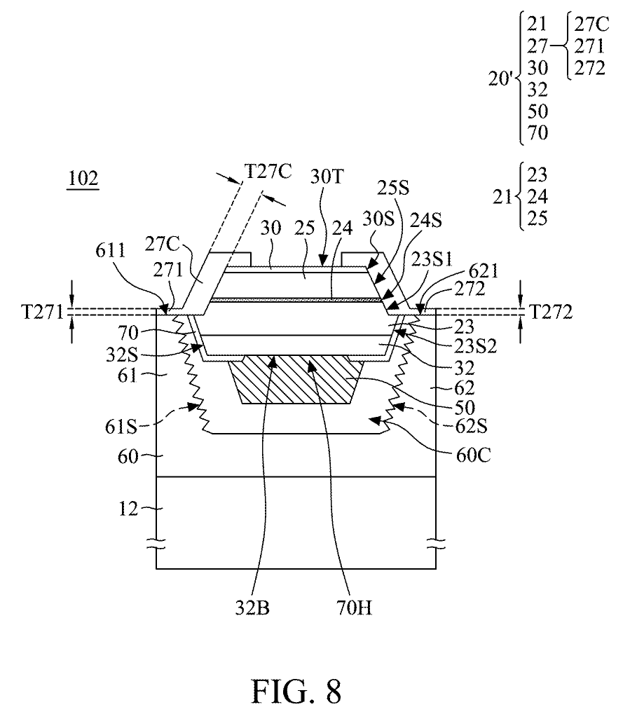

FIG. 8 shows a schematic partial cross-sectional view of a semiconductor device 102 according to other embodiments of the present disclosure. For the sake of simplicity, some components of the semiconductor device 102 are omitted in FIG. 8.

As shown in FIG. 8, the semiconductor device 102 includes one or more semiconductor elements 20’. The semiconductor element 20’ includes a semiconductor stack 21 and an insulating structure 27. In some embodiments, the insulating structure 27 is disposed on the semiconductor stack 21. As shown in FIG. 8, the main portion 27C covers the semiconductor stack 21. The sidewall 61S and the sidewall 62S may be inclined surfaces. Specifically, in some embodiments, the semiconductor stack 21 includes a first semiconductor structure 23, an active region 24, and a second semiconductor structure 25. In some embodiments, the first semiconductor structure 23 is closer to the substrate 12 than the second semiconductor structure 25. The semiconductor element 20’ may further include conductive connecting layers 30, 32, which are respectively disposed on the second semiconductor structure 25 and the first semiconductor structure 23. The semiconductor element 20’ may further include an electrode 50. The electrode 50 may be electrically connected to the first semiconductor structure 23. Optionally, the semiconductor element 20’ may further include the electrode 52 shown in FIG. 1A (not shown in FIG. 8), for example, disposed on the conductive connecting layer 30. In some embodiments, the conductive connecting layer 32 may be omitted from the semiconductor element 20’ when the electrode 50 directly forms favorable contact (e.g., ohmic contact) with the first semiconductor structure 23.

As shown in FIG. 8, a portion of the first semiconductor structure 23, the conductive connecting layer 32, and the electrode 50 are disposed in the cavity 60C, while other portions of the semiconductor element 20 extend upward beyond the upper surface 611 of the first supporting pillar 61 (or the upper surface 621 of the second supporting pillar 62). The insulating structure 27 is disposed to extend beyond the upper surface 611 (or the upper surface 621) and cover a sidewall 25S of the second semiconductor structure 25, a sidewall 24S of the active region 24, a portion of the sidewall 23S1 of the first semiconductor structure 23, and a sidewall 30S and a portion of a top surface 30T of the conductive connecting layer 30.

In some embodiments, the semiconductor element 20’ may optionally include a protective layer 70. The protective layer 70 is disposed in the cavity 60C. The protective layer 70 covers another portion of a sidewall 23S2 of the first semiconductor structure 23, and a sidewall 32S and a portion of a bottom surface 32B of the conductive connecting layer 32. In other words, a portion of the protective layer 70 may be located between the conductive connecting layer 32 and the electrode 50. The protective layer 70 includes an opening 70H. The electrode 50 may fill the opening 70H to be electrically connected to the conductive connecting layer 32 and the first semiconductor structure 23. Positions, relative relationships, material compositions, and structural variations of layers or structures in the present embodiments have already been described in detail in the foregoing embodiments and will not be repeated here.

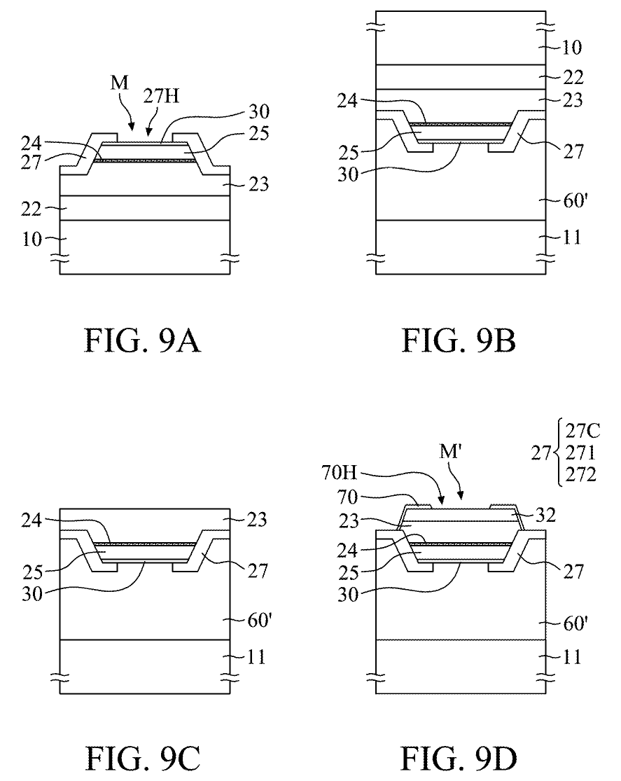

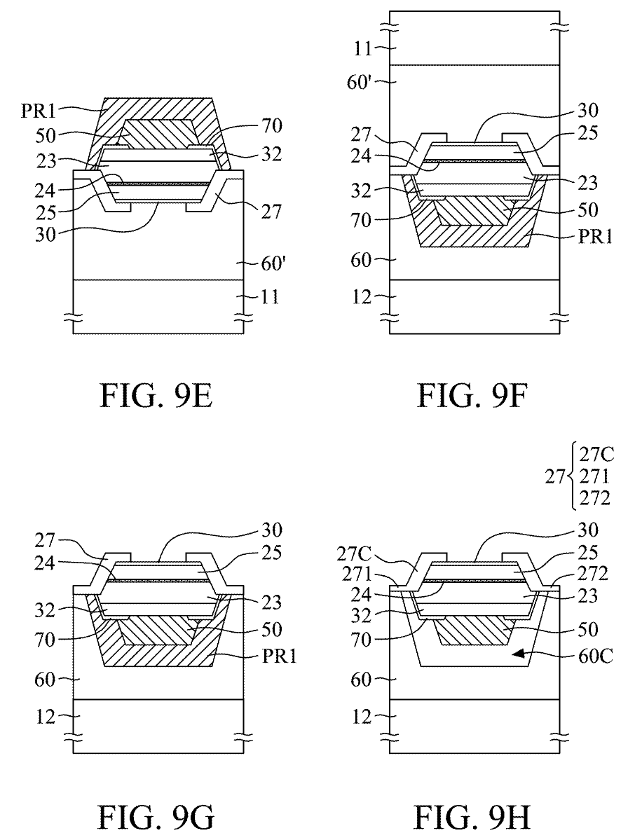

FIGS. 9A - 9H show schematic partial cross-sectional views of a semiconductor device 102 in different manufacturing processes according to other embodiments of the present disclosure. For the sake of simplicity, some components of the semiconductor device 102 are omitted in FIGS. 9A to 9H.

As shown in FIG. 9A, in some embodiments, a semiconductor layer 22, a first semiconductor structure 23, an active region 24, and a second semiconductor structure 25 are sequentially formed on the growth substrate 10. Next, a conductive connecting layer 30 is formed on the second semiconductor structure 25, and portions of the first semiconductor structure 23, the active region 24, the second semiconductor structure 25, and the conductive connecting layer 30 are removed to form a mesa region M on the first semiconductor structure 23. Then, an insulating structure 27 is formed on the first semiconductor structure 23, the second semiconductor structure 25, and the conductive connecting layer 30. An opening 27H is formed in the insulating structure 27 to expose a portion of the top surface of the conductive connecting layer 30.

After that, as shown in FIG. 9B, in some embodiments, the insulating structure 27 and the conductive connecting layer 30 are bonded to a temporary carrier 11 by means of a dielectric layer 60’. The dielectric layer 60’ may include a polymer material, such as benzocyclobutene (BCB), epoxy, polyimide, or silicone, and may also include alumina (Al₂O₃) or silicon oxide (SiO₂). The temporary carrier 11 may include a sapphire substrate or a glass substrate.

As shown in FIG. 9C, in some embodiments, the growth substrate 10 and the semiconductor layer 22 are removed. For example, a laser lift-off (LLO) process may be performed to remove the growth substrate 10 and the semiconductor layer 22. Next, as shown in FIG. 9D, a conductive connecting layer 32 may be formed on the first semiconductor structure 23. The conductive connecting layer 32 is formed, for example, by the deposition process. In some embodiments, a portion of the conductive connecting layer 32 and a portion of the first semiconductor structure 23 are removed to expose the insulating structure 27 and may form a mesa region M’. Optionally, after the conductive connecting layer 32 is formed, a protective layer 70 covering the first semiconductor structure 23 and the conductive connecting layer 32 may be formed, for example, by the deposition process.

Then, as shown in FIG. 9E, an electrode 50 and a sacrificial layer PR1 may be sequentially formed on the conductive connecting layer 32 and the first semiconductor structure 23, and the electrode 50 may be electrically connected to the first semiconductor structure 23. The electrode 50 and the sacrificial layer PR1 may be formed through the deposition process.

As shown in FIG. 9F, a bonding process is performed to bond the sacrificial layer PR1 and the like to the substrate 12 by means of the supporting layer 60. The supporting layer 60 may be in direct contact with the sacrificial layer PR1 and the insulating structure 27. Next, as shown in FIG. 9G, the dielectric layer 60’ and the temporary carrier 11 are removed. Then, as shown in FIG. 9H, the sacrificial layer PR1 is removed. In some embodiments, before removing the sacrificial layer PR1, a mask layer PR2 may be formed on portions of the conductive connecting layer 30, the second semiconductor structure 25, and the insulating structure 27 (referring to the foregoing embodiments). After that, using the mask layer PR2 as an etching mask, the insulating structure 27 is patterned so that the insulating structure 27 includes one or more extending portions (referring to FIG. 1B), and the mask layer PR2 is then removed.

In some embodiments, optionally, the insulating structure 27 may be further thinned to form the semiconductor device 102 as shown in FIG. 8. The thinning step may be performed, for example, by the etching process (e.g., ICP). The roughened structures of the sidewall 61S and the sidewall 62S are, for example, formed during the thinning step. In some embodiments, the thinning step may further increase the volume of the cavity 60C, thereby improving the success rate for transferring the semiconductor element 20’. Positions, relative relationships, material compositions, and structural variations of layers or structures in the present embodiments have already been described in detail in the foregoing embodiments and will not be repeated here.

FIG. 10 shows a schematic partial cross-sectional view of a semiconductor device 104 according to still other embodiments of the present disclosure. For the sake of simplicity, some components of the semiconductor device 104 are omitted in FIG. 10.

The semiconductor device 104 shown in FIG. 10 has a structure similar to that of the semiconductor device 102 shown in FIG. 8. As shown in FIG. 10, the semiconductor device 104 includes at least one semiconductor element 20”. The semiconductor element 20” includes a semiconductor stack 21 and an insulating structure 27. Differences between the semiconductor device 104 and the semiconductor device 102 lie in an appearance of the semiconductor stack 21 and the arrangement of the protective layer 70 and the insulating structure 27. In the semiconductor device 104, the insulating structure 27 is disposed in the cavity 60C and covers a portion of the sidewall 23S1 of the first semiconductor structure 23, the sidewall 32S of the conductive connecting layer 32, and a portion of the bottom surface 32B of the conductive connecting layer 32. In other words, a portion of the insulating structure 27 may be located between the conductive connecting layer 32 and the electrode 50. The insulating structure 27 exposes a portion of the conductive connecting layer 32 so that the electrode 50 can be electrically connected to the first semiconductor structure 23. In some embodiments, the protective layer 70 covers the sidewall 25S of the second semiconductor structure 25, the sidewall 24S of the active region 24, another portion of the sidewall 23S2 of the first semiconductor structure 23, and the sidewall 30S and a portion of the top surface 30T of the conductive connecting layer 30. Positions, relative relationships, material compositions, and structural variations of layers or structures in the present embodiments have already been described in detail in the foregoing embodiments and will not be repeated here.

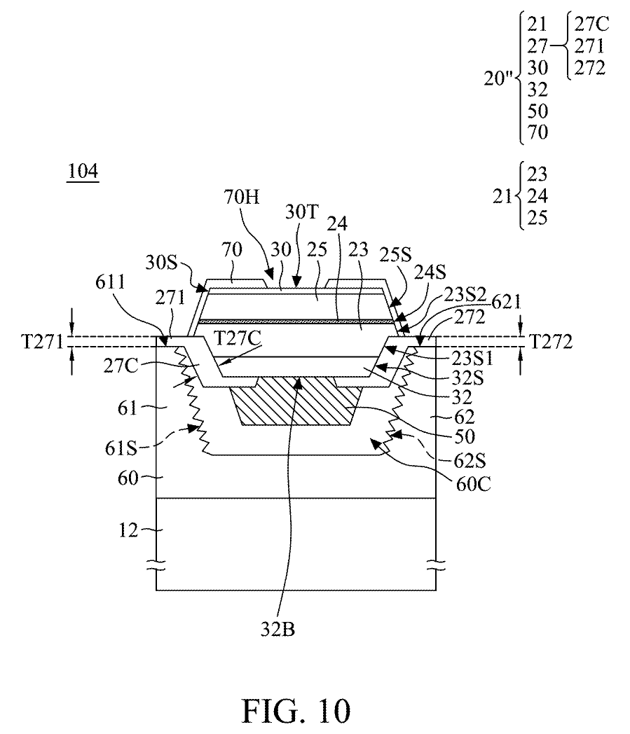

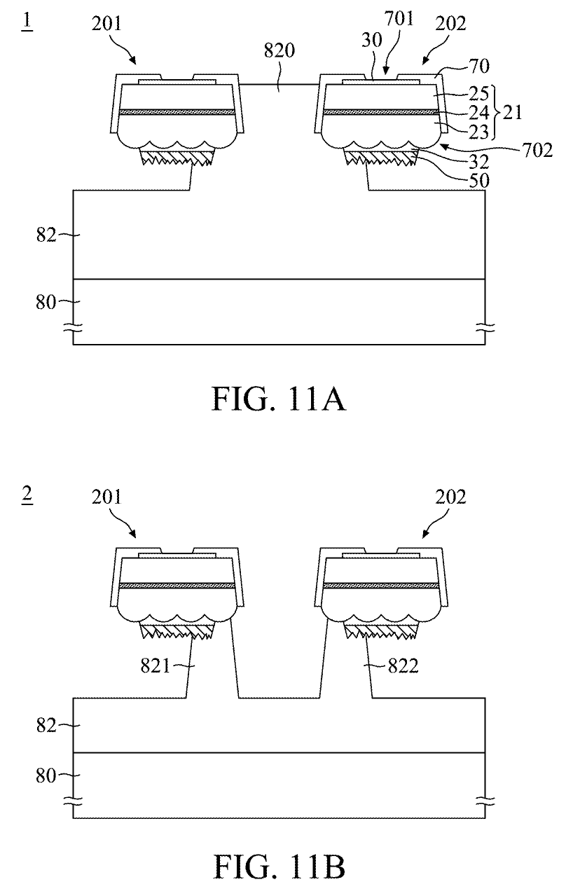

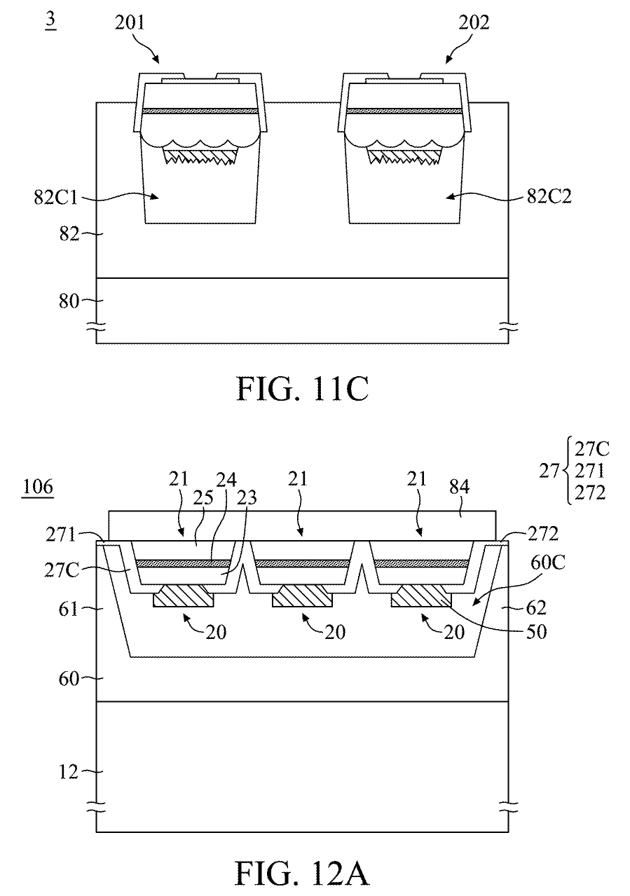

FIGS. 11A - 11C show schematic partial cross-sectional views of semiconductor devices 1, 2, and 3 according to different embodiments of the present disclosure. For the sake of simplicity, some components of the semiconductor devices 1, 2, and 3 are omitted in FIGS. 11A -11C. FIGS. 11A, 11B and 11C, show another type of semiconductor device applicable to stamp transfer.

As shown in FIG. 11A, in some embodiments, the semiconductor device 1 includes a substrate 80 and a supporting member 82 disposed on the substrate 80. The semiconductor device 1 includes a first semiconductor element 201 and a second semiconductor element 202. In some embodiments, the first semiconductor element 201 and the second semiconductor element 202 may not include an insulating structure 27. Material of the substrate 80 may refer to that of the substrate 12, and material of the supporting member 82 may refer to that of the supporting layer 60. In the first semiconductor element 201 and the second semiconductor element 202, the protective layer 70 covers the semiconductor stack 21 and includes a first opening 701 and a second opening 702. The conductive connecting layer 30 may be exposed through the first opening 701, and the conductive connecting layer 32 and the electrode 50 may be exposed through the second opening 702. In some embodiments, the supporting member 82 includes a protruding portion 820, and the first semiconductor element 201 and the second semiconductor element 202 are respectively connected to two sides of the protruding portion 820 of the supporting member 82. In some embodiments, the first semiconductor element 201 and the second semiconductor element 202 directly contact the protruding portion 820, thereby maintaining positions of the first semiconductor element 201 and the second semiconductor element 202 and improving the success rate of subsequent transfer of the first semiconductor element 201 and the second semiconductor element 202.

As shown in FIG. 11B, in some embodiments, the semiconductor device 2 includes a substrate 80 and a supporting member 82 disposed on the substrate 80. In some embodiments, the supporting member 82 includes a first protruding portion 821 and a second protruding portion 822. The first protruding portion 821 and the second protruding portion 822 are spaced apart from each other and are not in direct contact. The first semiconductor element 201 and the second semiconductor element 202 are respectively connected to the first protruding portion 821 and the second protruding portion 822.

As shown in FIG. 11C, in some embodiments, the semiconductor device 3 includes a substrate 80 and a supporting member 82 disposed on the substrate 80. In some embodiments, the supporting member 82 includes a cavity 82C1 and a cavity 82C2. The first semiconductor element 201 and the second semiconductor element 202 may be respectively disposed corresponding to the cavity 82C1 and the cavity 82C2. In the first semiconductor element 201 and the second semiconductor element 202, since both side surfaces are in direct contact with the supporting member 82, a more stable connection can be achieved as compared with the embodiments shown in FIGS. 11A and 11B. Positions, relative relationships, material compositions, and structural variations of layers or structures shown in FIGS. 11A - 11C have already been described in detail in the foregoing embodiments and will not be repeated here.

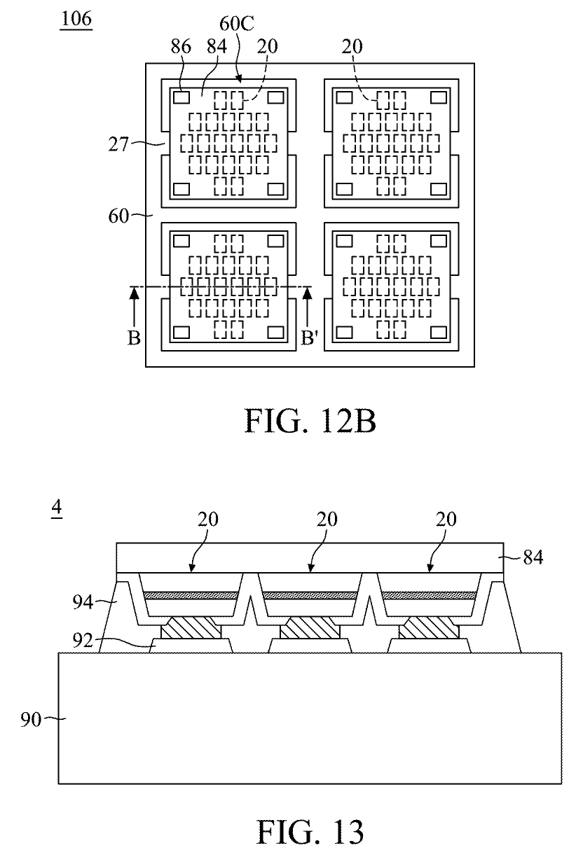

FIG. 12A shows a schematic partial cross-sectional view of a semiconductor device 106 according to still other embodiments of the present disclosure, and FIG. 12B shows a schematic partial top view of the semiconductor device 106 according to still other embodiments of the present disclosure. The cross-sectional view shown in FIG. 12A does not completely correspond to the top view shown in FIG. 12B. Specifically, FIG. 12A is, for example, a schematic cross-sectional view taken along line B-B’ in FIG. 12B. For the sake of simplicity, some components of the semiconductor device 106 are omitted in FIGS. 12A, 12B. For example, although the cross section along line B-B’ passes through six semiconductor elements 20, only three semiconductor elements 20 are illustrated in FIG. 12A.

As shown in FIG. 12A, in some embodiments, the semiconductor device 106 includes a substrate 12 and a supporting layer 60 disposed on the substrate 12. In a cross-sectional view, the supporting layer 60 includes a first supporting pillar 61 and a second supporting pillar 62 that are separated from each other. The semiconductor device 106 also includes a plurality of semiconductor elements 20, and each semiconductor element includes a semiconductor stack 21 and an insulating structure 27 disposed on the semiconductor stack 21. The insulating structure 27 includes a main portion 27C, a first extending portion 271, and a second extending portion 272. The first extending portion 271 and the second extending portion 272 are separated from each other. The main portion 27C covers the semiconductor stack 21, and the first extending portion 271 and the second extending portion 272 respectively extend outward from the main portion 27C to the first supporting pillar 61 and the second supporting pillar 62 and are respectively connected to the first supporting pillar 61 and the second supporting pillar 62. The first thickness of the first extending portion 271 and the second thickness of the second extending portion 272 are less than the third thickness of the main portion 27C.

In some embodiments, the semiconductor device 106 further includes a connecting layer 84. The connecting layer 84 is, for example, a semiconductor layer. In some embodiments, the connecting layer 84 may include a binary group III-V semiconductor material, such as GaN, GaAs, or GaP. As shown in FIG. 12A, the connecting layer 84 is disposed on the plurality of semiconductor elements 20 and connects these semiconductor elements 20 together. That is, the connecting layer 84 covers and directly contacts the semiconductor stack 21 of each semiconductor element 20. In some embodiments, the plurality of semiconductor elements 20 may be connected to one another through the connecting layer 84, and the plurality of semiconductor elements 20 may share the first extending portion 271 and the second extending portion 272.

As shown in FIG. 12B, in some embodiments, each connecting layer 84 in the semiconductor device 106 may correspond to twenty semiconductor elements 20. If one connecting layer 84 and the plurality of semiconductor elements 20 connected thereto are regarded as one group, FIG. 12B shows four groups of semiconductor elements 20. Each group of semiconductor elements 20 may be connected to the supporting layer 60 through its respective insulating structure 27. In some embodiments, the semiconductor device 106 may further include alignment marks 86. In some embodiments, the alignment marks 86 may be located on the connecting layer 84. For example, in a top view, one alignment mark 86 may be disposed at each corner of each group of semiconductor elements 20. With such an arrangement, in the subsequent process of transferring the semiconductor elements 20, multiple semiconductor elements 20 may be transferred simultaneously on a group-by-group basis, and the semiconductor elements 20 may be aligned to specific positions at a transfer destination by means of the alignment marks 86. Accordingly, transfer efficiency can be further improved. On the other hand, since the multiple semiconductor elements 20 within the same group can be connected to one another through the insulating structure 27 and the connecting layer 84, walkway space can be saved as compared with a plurality of separately isolated semiconductor elements 20, which is advantageous for applications requiring further reduction in spacing between elements.

FIG. 13 shows a schematic cross-sectional view of a semiconductor assembly 4 according to some embodiments of the present disclosure, such as a partial cross-sectional view illustrating the transfer of the semiconductor device 106 onto a semiconductor base 90 (e.g., a CMOS backplane). For the sake of simplicity, some components of the semiconductor assembly 4 are omitted in FIG. 13.

As shown in FIG. 13, in some embodiments, the semiconductor assembly 4 includes a semiconductor base 90. The semiconductor base 90 may be a bulk semiconductor substrate or a composite substrate including different materials. For example, the semiconductor base 90 may be formed of an elemental semiconductor (e.g., silicon or germanium), a compound semiconductor (e.g., silicon carbide (SiC), gallium arsenide (GaAs), indium arsenide (InAs), or indium phosphide (InP)), or an alloy semiconductor (e.g., SiGe, SiGeC, GaAsP, or GaInP). The semiconductor base 90 may be a semiconductor-on-insulator (SOI) substrate. The SOI substrate may include a base substrate, a buried oxide layer disposed on the base substrate, and a semiconductor layer disposed on the buried oxide layer. Alternatively, the semiconductor base 90 may be a semiconductor wafer (e.g., a silicon wafer or another suitable semiconductor wafer).

The semiconductor base 90 may also include various p-type doped regions and/or n-type doped regions formed by processes such as ion implantation and/or diffusion. In some embodiments, the doped regions may be configured to form transistors, photodiodes, and/or light-emitting diodes. The semiconductor base 90 may include various isolation features (e.g., shallow trench isolation (STI) features) for separating different device regions in the semiconductor base 90. Steps for forming the shallow trench isolation may include etching trenches in the semiconductor base 90 and filling the trenches with an insulating material (e.g., silicon oxide, silicon nitride, or silicon oxynitride). The filled trenches may have a multilayer structure (e.g., a thermal oxide liner and silicon nitride filled in the trenches). A chemical mechanical polishing (CMP) process may be performed to polish away excess insulating material and planarize the upper surfaces of the isolation features.

The semiconductor base 90 may include various conductive features (e.g., conductive lines or vias). In some embodiments, the conductive features may be formed of aluminum (Al), copper (Cu), or tungsten (W). In some embodiments, the semiconductor base 90 includes a plurality of conductive pads 92. The plurality of semiconductor elements 20 connected through the connecting layer 84 may be transferred above the semiconductor base 90, and the electrodes of the semiconductor elements 20 are connected to the corresponding conductive pads 92. Accordingly, the semiconductor elements 20 are electrically connected to the semiconductor base 90.

As shown in FIG. 13, in some embodiments, the semiconductor assembly 4 further includes an underfill material 94. The underfill material 94 is located between the semiconductor base 90 and the semiconductor elements 20 (or the connecting layer 84) to fill the gaps between the semiconductor base 90 and the semiconductor elements 20, thereby preventing moisture or dust from entering the semiconductor elements 20 to protect the semiconductor assembly 4 and improve the overall yield.

In conclusion, according to the embodiments of the present disclosure, a semiconductor device is provided. The semiconductor device can improve transfer success rate and structural stability through process and structural design. The semiconductor device may be applicable to the mass transfer of micro-LED dies and improve stress distribution during the transfer process and reduce the risk of structural deformation, thereby improving manufacturing efficiency and product yield. In some embodiments, the semiconductor device may include extending portions. The extending portions may be part of the insulating structure in the semiconductor element without the need to additionally form other components, thereby effectively reducing cost and simplifying process steps.

Although the present disclosure has been described in considerable detail with reference to certain embodiments thereof, the disclosure is not for limiting the scope of the invention. Persons having ordinary skill in the art may make various modifications and changes without departing from the scope and spirit of the disclosure. Therefore, the scope of protection of the present disclosure shall be defined by the appended claims.

What is claimed is:

1. A semiconductor device, comprising:
a substrate;
a supporting layer disposed on the substrate, wherein in a cross-sectional view, the supporting layer comprises a first supporting pillar; and
a semiconductor element, comprising:
a semiconductor stack; and
an insulating structure disposed on the semiconductor stack, and comprising a main portion covering the semiconductor stack and a first extending portion extending outward from the main portion to the first supporting pillar;
wherein the first extending portion comprises a first thickness, and the main portion comprises a second thickness greater than the first thickness.

2. The semiconductor device according to claim 1, wherein the main portion and the first extending portion have different materials.

3. The semiconductor device according to claim 1, wherein a ratio of the first thickness to the second thickness is between 1/4 to 1/60.

4. The semiconductor device according to claim 1, wherein the main portion comprises a first sublayer and a second sublayer, and the first sublayer and the second sublayer comprise different Mohs hardnesses.

5. The semiconductor device according to claim 4, wherein the first sublayer and the second sublayer have different thicknesses.

6. The semiconductor device according to claim 1, wherein the first supporting pillar comprises a sidewall with a roughened structure facing the semiconductor stack.

7. The semiconductor device according to claim 1, wherein the first extending portion comprises a void.

8. The semiconductor device according to claim 1, wherein the semiconductor stack comprises a first semiconductor structure and a second semiconductor structure, a width of the first semiconductor structure first gradually increases and then gradually decreases in a direction away from the second semiconductor structure.

9. The semiconductor device according to claim 8, wherein the insulating structure is devoid of covering a portion of the first semiconductor structure where the width gradually decreases.

10. The semiconductor device according to claim 1, wherein the supporting layer further comprises a second supporting pillar, and the insulating structure further comprises a second extending portion outward from the main portion to the second supporting pillar.

11. The semiconductor device according to claim 10, wherein the second extending portion comprises a third thickness different from the first thickness.

12. The semiconductor device according to claim 1, wherein the semiconductor stack comprises an active region and the first supporting pillar comprises an upper surface, and the active region is at a higher elevation than the upper surface.

13. A semiconductor device, comprising:
a substrate;
a supporting layer disposed on the substrate, wherein in a cross-sectional view, the supporting layer comprises a first supporting pillar and a second supporting pillar; and
a plurality of semiconductor elements, wherein each of the plurality of semiconductor elements comprises:
a semiconductor stack; and
an insulating structure comprising a main portion covering the semiconductor stack, a first extending portion extending outward from the main portion to the first supporting pillar, and a second extending portion extending outward from the main portion to the second supporting pillar.

14. The semiconductor device according to claim 13, further comprising: a connecting layer disposed on the plurality of semiconductor elements.

15. The semiconductor device according to claim 14, further comprising: an alignment mark located on the connecting layer.

16. The semiconductor device according to claim 15, wherein the alignment mark is disposed on a corner of the connecting layer.

17. The semiconductor device according to claim 14, wherein the connecting layer comprises a binary III-V semiconductor material.

18. The semiconductor device according to claim 13, wherein the first extending portion comprises a first thickness, the second extending portion comprises a second thickness, and the main portion comprises a third thickness greater than the first thickness and the second thickness.

19. The semiconductor device according to claim 13, wherein the first supporting pillar or the second supporting pillar comprises a sidewall with a roughened structure facing the plurality of semiconductor elements.

20. The semiconductor device according to claim 13, wherein the insulating structure continuously covers the semiconductor stacks of the plurality of semiconductor elements.
